(19) United States
(12) Patent Application Publication
(10) Pub. No.: US 2009/0312954 A1
(43) Pub. Date: Dec. 17, 2009

(54) Sensor

(75) Inventor: Mikko Utriainen, Mikkeli (FI)

Correspondence Address: BIRCH STEWART KOLASCH & BIRCH, PO BOX 747, FALLS CHURCH, VA, 22040-0747, US

(73) Assignee: Environics Oy, Mikkeli (FI)

(21) Appl. No.: 12/226,482

(22) PCT Filed: Apr. 23, 2007
(86) PCT No.: PCT/FI2007/000107

§ 371 Date: Mar. 4, 2009

(30) Foreign Application Priority Data
Apr. 21, 2006 (FI) 20060389

(51) Int. Cl. H01L 29/24; G06F 19/00; G01N 27/00; G01K 17/00

(52) U.S. Cl. 702/23; 257/43; 324/71.1; 374/31; 257/E29.1; 374/E17.001

(57) ABSTRACT

In general, the invention relates to gas sensing techniques as such, but more specifically, to a sensor structure that comprises a buried electrode structure in the sensor layers, the structure being arranged to be applicable in the related devices and/or measurements. The invention relates also to a measurement method of sensor resistance, which method comprises a step of utilisation having a bias voltage or a grounding applied to the buried electrode.

In a very general level the current invention belongs to the field of sensors, but in more specifically concerns a solid state micro gas sensor component as indicated in the preamble of an independent claim on the gas sensor structure. The invention also concerns a measurement method as indicated in the preamble of an independent claim thereof. The invention also concerns a gas sensor matrix of gas sensors as indicated in the preamble of an independent claim thereof. The invention also concerns gas measurement device with a gas sensor as indicated in the preamble of an independent claim thereof. The invention also concerns gas measurement device with a gas sensor matrix of gas sensors as indicated in the preamble of an independent claim thereof. The invention also concerns a software program product as indicated in the preamble of an independent claim thereof.

Metal oxide semiconductor (MOS) gas sensor is a mature innovation [1, 2] and has many advantageous features such as high sensitivity, fast response and recovery, versatile selectivity through operational temperature and sensor materials as well as good capabilities for low-cost mass production and small size mobile applications. It has been widely applied in automatic ventilation control systems, household applications and recently also in toxic gas sensor devices. The known sensor technology as such is suitable for measuring various volatile organic compounds, toxic chemical vapours as well as gases such as NO₂, CO, CH₄ and H₂S.

However, many drawbacks can be addressed restricting the use of MOS gas sensors more widely. Those include: frequently observed drift, poor quality due to reproducibility challenges, narrow dynamic range and non-linear response. The main consequences of these drawbacks are poor accuracy and poor precision. Therefore, typical application is to trigger predetermined less-accurate concentration level of the given gas—not performing quantitative measurement for wide concentration range.

Furthermore, the basic feature of the MOS gas sensor is high operational temperature, typically 200-400° C. In order to reach that, the known MOS sensor requires integrated heater resistor. If the mass and heat conductivity of the sensor is high, the power consumption of the sensor will be also high. That feature restricts significantly capabilities for mobile applications and for consumer electronics. An excellent solution of the known techniques for reducing the power consumption of the MOS gas sensor is so called micro hot plate structure [3-6] where sensor is miniaturized to only a few micrometer thickness as illustrated in FIG. 1. The basis of power reduction is low thermal mass and possibility to the pulsed heating. The micro hot plate structure facilitates also novel measurement principles. An example is to use fast time sequence to apply variable operational temperature. Measurements carried out in several temperature windows in few seconds total sequence time can basically improve the selectivity because chemical interaction (and reaction) between specific gaseous species and sensor surface is evidently temperature dependent. However, this is not straightforward advantage because the drift of the sensor signal becomes often even worse than in the constant temperature mode.

The gas sensor material of the conventional known MOS gas sensor as such is prepared by thick film technology or through colloidal liquids by drop deposition [4, 5] while the micro hot plate based structures are prepared by using semiconductor CMOS and MEMS technologies. The problems in quality and reproducibility are generally associated to the thick film sensor material. However, it has been demonstrated that the MOS gas sensor material can be prepared by vapour phase deposited thin film technologies also. In that case, both chemical vapour deposition (CVD) and physical vapour deposition (PVD) methods are basically feasible. A good quality and reproducibility by the thin film methods is expected. However, it is commonly believed that high surface area and porous microstructure are important properties to obtain sufficient sensitivity. These properties are easily reached by thick films or extremely porous thin films like those formed by nanometer size grains. High quality and reliability has not been the main aim for the developers so far, although especially CVD-type thin films exhibit evidently good performance in that respect. Of the thin film deposition methods, PVD thin films have been more favourable than CVD thin films. That is because the combination of CVD sensor material to the micro hot plate structure is challenging for the fabrication and, on the other hand, PVD sensor materials possess typically more porous microstructure than dense CVD thin films.

Furthermore, the typical cost-efficient manufacturing favours outsourcing the fabrication of CMOS components, like micro hot plate platforms, to the CMOS foundries, like proposed by Muller et al [6]. However, typically CMOS foundry does not have processes available to deposit less-common sensor materials, like semiconductor metal oxides and transition metal catalysts. Therefore sensor manufacturer needs to focus on development of the metal oxide sensor material on top of the pre-fabricated platform and that last, in-house, process step forms the core technology expertise. In order to reach cost-efficiency, the thick film processes are typically favoured.

However, the current invention focuses to the commercially less-common thin films as such and, especially to thin films with dense microstructure. The dense thin film materials can exhibit significantly different transducer mechanisms than porous materials since in the latter case the grain boundary potential apparently dominates whereas in the former case the role of surface, interface and contact potentials can be much more significant. If the contribution of these factors is not controlled, the result may be regarded as poor quality and poor reproducibility. This aspect is not always understood properly when MOS gas sensors are designed.

The availability of accurate and reliable MOS gas sensor would enhance significantly the capabilities of the sensor in its present applications as well can be the way to find new applications. The present invention shows an innovative MOS gas sensor chip, component and measurement principle to achieve the high accuracy and good precision and overcome the problems of the present state-of-art.

### REFERENCES TO KNOWN TECHNIQUES (1-7)

1. Taguchi, N., Jpn Patent 45-38200, 1962.
2. Seiyama, T., Kato, A., Fukiishi, K. and Nakatini, M., Anal. Chem. 34 (1962) 1502-1503.
3. Gaitan, M., Suehle, J. S., Semancik, S., Cavicchi, R. E., Pat. WO9410822, 1994
4. Fau, P., Sauvan, M., Trautweiler, S., Nayral, C., Erades, L., Maisonnat, A. and Chaudret, B., Sens. Actuators B 78 (2001) 83-88.
5. Briand, D., Krauss, A., van der Schoot, B., Weimar, U., Barsan, N., Göpel, W. and de Rooij, N., Sens. Actuators B 68 (2000) 223-233.
6. Muller, G, Friedberger, A., Kreisl, P., Ahlers, S., Schultz, O. and Becker, T., Thin Solid Films 436 (2003) 34-45.
7. Reeves, G. K. and Harrison, H. B., IEEE Electron Device Letters (1982) 111-113.

The micro hot plate based MOS gas sensors as such in known techniques contain the crucial elements such as a sensing layer, sensing electrodes, heater electrodes and an insulator layers between them as shown in the FIG. 1, which illustrates known techniques as such concerning sensor chip design and position of the active area in the chip per se.

It is an aim of the invention to solve, or at least mitigate, the problems of the known techniques. The aim is achieved with embodiments of the invention as relating to a gas sensor structure.

A micro hot-plate solid-state gas sensor structure according to the invention is characterized in that what has been indicated in the characterizing part of an independent claim thereof. A measurement method according to the invention has been characterized in that what has been indicated in the characterizing part of an independent claim thereof. A gas sensor matrix according to the invention has been characterized in that what has been indicated in the characterizing part of an independent claim thereof. A gas measurement device with a gas sensor according to the invention has been characterized in that what has been indicated in the characterizing part of an independent claim thereof. A gas measurement device with a gas sensor matrix of gas sensors according to the invention has been characterized in that what has been indicated in the characterizing part of an independent claim thereof. A software program product according to the invention has been characterized in that what has been indicated in the characterizing part of an independent claim thereof.

Further embodiments of the invention are shown in the dependent claims.

The present invention concerns a structure for a micro hot plate based MOS gas sensor with thin film, preferably CVD thin film, sensor materials. It also involves an electronic measurement principle as well as it involves fabrication methods to improve the quality of the device. In a combination of those mentioned, the embodiments of the invention sensor drift can be controlled, sensor fabricated in a reproducible manner as well as the dynamic range extended and the selectivity to gases enhanced in respect to the known techniques. Generally, the sensor reliability and accuracy can be thus enhanced and new utilisation of applications expected.

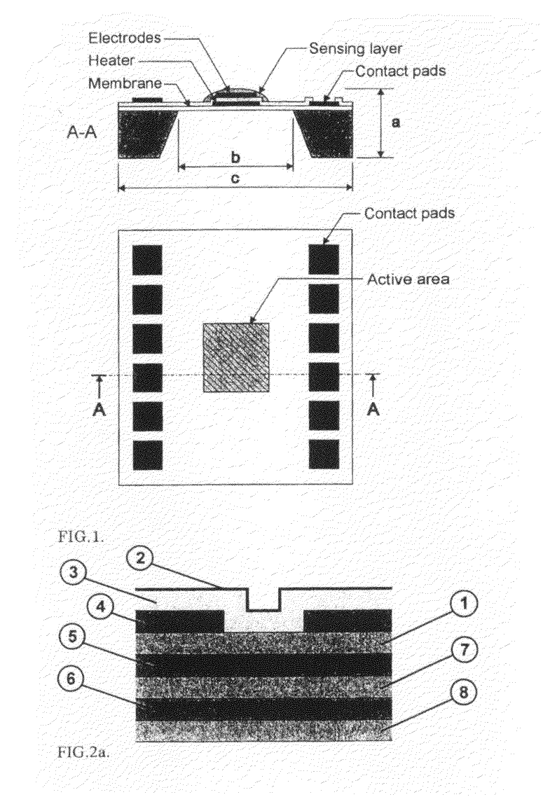

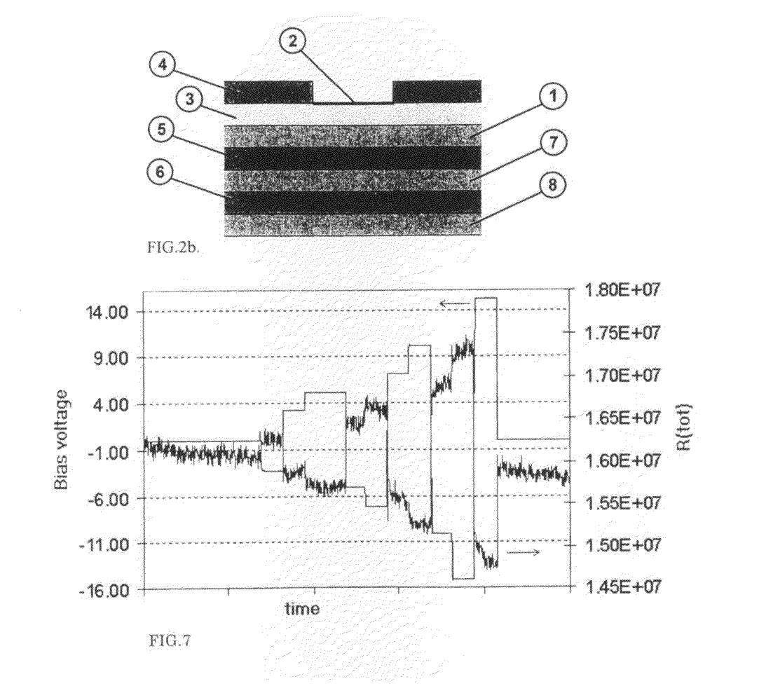

Because the FIG. 1 illustrates known techniques as such, in the following the embodiments of the invention are explained in more detail as non-restrictive examples by making a reference to the following FIGS. 2a-8 in which

FIG. 2a illustrates a cross section of an active area according to an embodiment of the invention,

FIG. 2b illustrates a cross section of an active area according to another embodiment of the invention,

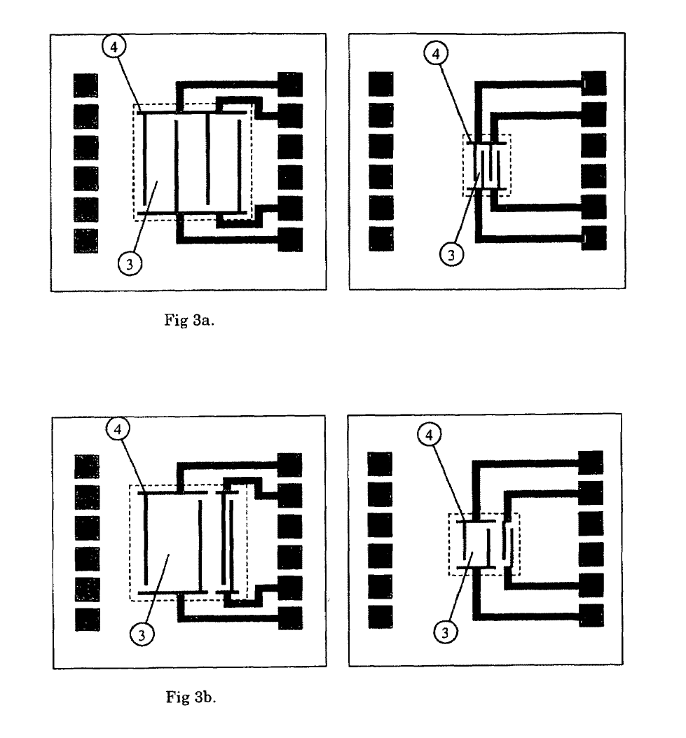

FIG. 3a illustrates a top view of two active areas according to an embodiment of the invention,

FIG. 3b illustrates a top view of a multielectrode configuration of two active areas according to another embodiment of the invention,

FIG. 3c illustrates a view of a multielectrode configuration and transmission lines according to an embodiment of the invention,

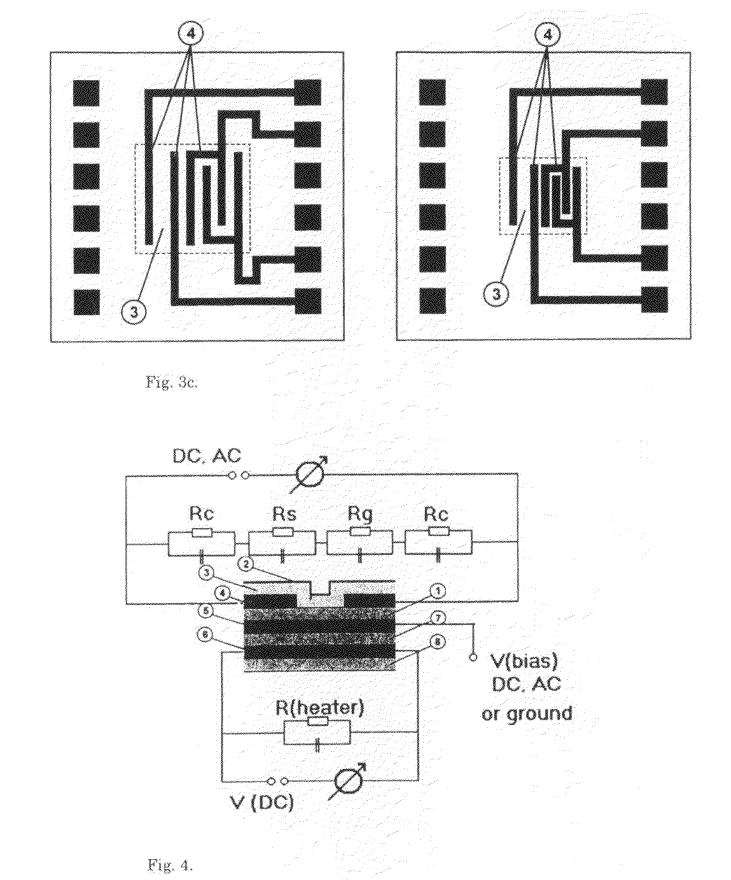

FIG. 4 illustrates a measurement and control circuit according to an embodiment of the invention,

FIG. 5 illustrates a relationship of contact resistance and sheet resistance,

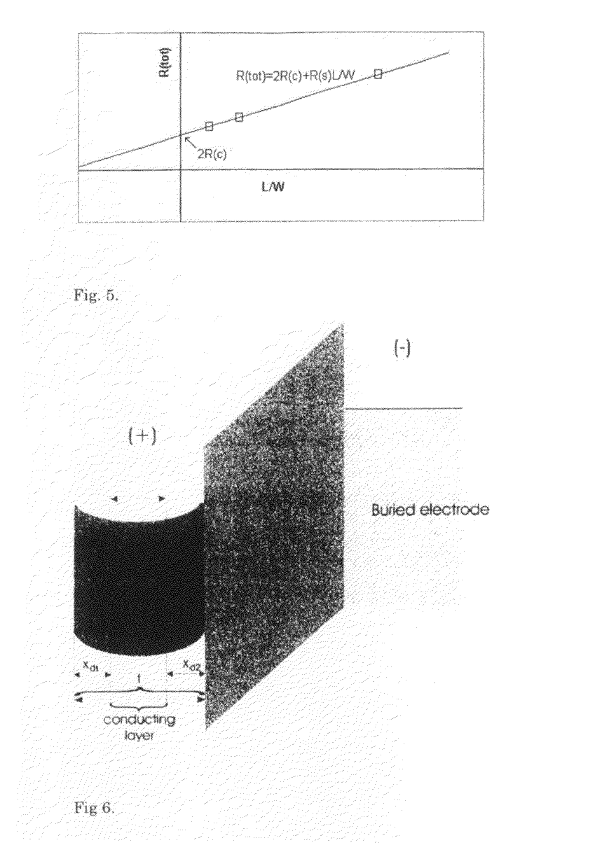

FIG. 6 illustrates an energy diagram,

FIG. 7 illustrates the influence of buried electrode bias on the total resistance of the sensor, and

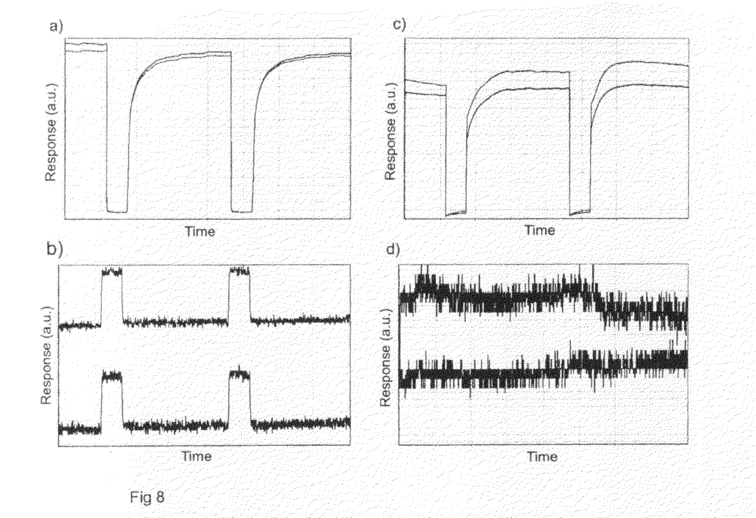

FIG. 8 demonstrates the role of the heater material according to an embodiment of the invention.

The same reference numerals are used for same kind of parts in the Figs, although the parts should not be necessary exactly the same in the shown embodiments. The various embodiments of the invention are combinable in suitable part.

Nevertheless, as shown in the FIGS. 2a and 2b, the micro hot plate structure according to an embodiment of the present invention contains elements per se in its active area as a known devices, but in addition also characteristically an additional buried metal electrode layer 5 between the sensing layer 2,3,4 and the heater metal layer 6 and again insulator layers 1,7,8 between each metal layer. Such a structure improves the accuracy of the measurement and is cost-effective to manufacture. The number of metal layer is not restricted only to the shown, but in an embodiment of the invention there can be also two metal layers. According to an embodiment of the invention there can be also even more metal layers for a purpose of the kind of the layer 5 but with a different measures to be operated with the layer 5 in parallel, in series and/or alternatively. According to an embodiment of the invention each layer can be insulated with an insulating layer like the layer 1,7,8, however not being limited to only the layer 1,7,8.

According to an embodiment of the invention, the semiconductor metal oxide layer has well-controlled microstructure, dopant concentration and/or lattice imperfections, such as oxygen vacancies. An embodiment of the invention concerning a gas sensor structure is not easily influenced by the prolonged heating and operation. Preferably, that is obtained, while manufacturing, by applying CVD-type ALD (Atomic Layer Deposition) thin film deposition method or other deposition method facilitating good control and reproducibility. The thickness of the semiconductor oxide layer 3 is close to Debye length of the employed oxide semiconductor. In an embodiment of the invention a practical Debye length is in the range 10-100 nm. A preferred semiconductor material is a metal oxide exhibiting n-type semiconductor properties and surface potential variations due to exposes to low concentrations of volatile compounds or gases in the elevated temperatures. Examples of such materials are SnO₂, WO₃, In₂O₃ and TiO₂.

According to an embodiment of the invention, the selectivity of the metal oxide is tailored by applying a catalytic overlayer 2 on top of the semiconductor oxide layer in a manufacturing phase. Those materials are typically transition metals, noble metals as well as earth alkaline and rare earth metals and/or their oxides. According to an embodiment of the invention a theoretical thickness of the overlayer is in the range of one nanometer. According to another embodiment of the invention a theoretical thickness of the overlayer is less than one nanometer. According to an embodiment of the invention a theoretical thickness of the overlayer is less than ten nanometers. According to another embodiment of the invention a theoretical thickness of the overlayer is less than 20 nm. According to an embodiment of the invention a theoretical thickness of the overlayer is less than fifty nanometers. According to an embodiment of the invention the theoretical thickness of the overlayer is between 5 and 15 nm. According to an embodiment of the invention the theoretical thickness of the overlayer is between 12 and 25 nm.

According to an embodiment of the invention the overlayer material is uniformly a monolayer. However, according to another embodiment of the invention, the overlayer material is not necessarily uniformly a monolayer, but can be distributed forming nanometer-scale islands. The distribution and structure of the overlayer depends on the applied material and the fabrication process details. Preferably, the overlayer is deposited by using conventional thin film deposition methods as such.

In FIG. 2a, the reference numerals for the cross-section view of the active area of a first preferred embodiment are as follows: 1, 7 and 8=insulator layers, 2=catalyst overlayer, 3=semiconductor metal oxide layer, 4=metal electrode layer, 5=buried electrode, 6=heater and temperature sensor resistor. The FIG. 2b follows the same way of using reference numerals, although the layers 2, 3 and 4 are in a different order than in FIG. 2a. According to an embodiment of the invention exemplary illustrated via FIG. 2b the metal oxide 3 provides an adhesion enhancement for the metal electrode 4 while in the embodiment illustrated in FIG. 2a, an additional adhesion enhancement layer is required between metal electrode and first insulating layer. According to an embodiment of the invention, electrode can be a nobel metal. According to such an embodiment the electrode is of gold (Au) and/or Platinum. According to an embodiment also other platinum metals can be used, for very reactive gases, such as iridium. According to an embodiment of the invention the adhesion layer can be of Ti, TiW-alloy or Cr.

In an embodiment of the present invention, the electrode configuration is a conventional electrode pair as shown in FIG. 3a, which shows a schematic top view of two examples on electrode configurations for two different active area sizes. The active area is indicated by a dashed line. The electrode configuration is formed by a pair of interdigital electrodes. Active area influence on the mechanical strength of the structure of the active area, but also on sensitivity. The structure with smaller dimensions is mechanically stronger in respect to tensile stress, but using a larger active area as in FIG. 3a the sensitivity can be higher than in the small active area. According to an embodiment of the invention number of the interdigital finger electrodes, as shown in FIG. 3a embodiments, can be the same as in the figure. According to an embodiment of the invention number of the interdigital finger electrodes is less than several hundreds, preferably less than 100. According to an embodiment of the invention number of the interdigital finger electrodes is less than several hundreds, preferably less than 10. According to an embodiment of the invention such a gas sensor having a large active area can comprising such an amount of the finger electrodes, as referred to the large sensor type. According to another embodiment of the invention such a gas sensor having a small active area can comprising such an amount of the finger electrodes, as referred to the small sensor type.

According to an embodiment of the invention the interdigital electrode gap is similarly wide as the electrodes. According to an embodiment of the invention the interdigital electrode gap is less than 5 times wider as the electrodes. According to an embodiment of the invention the interdigital electrode gap is less than 10 times wider as the electrodes. The wide gap enhances sensitivity to gases. The main part of the total sensor resistance originates from one metal oxide layer 3 between electrodes.

In another preferred embodiment, the electrode configuration is a multielectrode configuration as shown in the FIG. 3b. In the case of multielectrode configuration the pattern resembles so called transmission line model test pattern that enables distinguishing contact and sheet resistances. According to an advantageous embodiment of the invention the electrode width is constant for all electrodes for the shown example in FIG. 3b, but is not limited only there to.

FIG. 3b shows two differently sized active area configurations. In this exemplary embodiment of FIG. 3b, four electrodes are forming three electrode pairs each with different gap width, which is a conventional electrode pattern for the transmission line model. In a preferred embodiment of the present invention, as shown in FIG. 3c, a modified transmission line model test pattern is made by a combination of interdigital electrode structure and the conventional electrode strips as such. According to an embodiment of the invention the finger like structures of the transmission line can be utilised also as electrodes.

The active area structure as exemplary embodied in accordance to FIG. 3a enhances the sensitivity. However, using the structures as shown in FIGS. 3b and/or 3c also accuracy can be gained. This is important especially for distinguishing Rs and Rc from each other reliably and so to control the measurements and/or the sensing of the gas.

In order to control accurately the heater power, characteristic feature of the present invention is also that the favoured material in the heater layer 6 is thermally stable and inert metal that exhibit high thermal coefficient of resistance in the 200-400° C. operational temperature range. That facilitates high accuracy for the temperature measurement and control that is crucial for accurate measurements. Examples of such materials are tungsten and platinum.

In order to manufacture a sensor according to an embodiment of the invention, a metal oxide semiconductor layer 3 is processed as a similar step as other layers 1,4,5,6,7,8. Such a method comprises process steps for deposition of the thin film and its patterning either by wet etching or dry etching. Such an approach simplifies the integration of CVD-type thin film process to the micro hot plate structure.

According to an embodiment of the invention the sensor area is a plane like structure. According to an embodiment of the invention the sensor area has several such plane like structures in parallel or in series to be operated as gas sensors. According to an embodiment of the invention the sensor area is curved into a non-planar structure. According to an embodiment of the invention the sensor area is curved into tube-like structure, to provide the gas as flow through the tube.

In an embodiment of the invention concerning a matrix of gas sensors according to an embodiment of the invention, such a matrix comprises one type of gas sensors, large sensor type or small sensor type, of which sensors all have same active area structure. However, the sensitive layers 2,3 are not necessary of same material, but can be different so to provide different selectivity to gases. In an example, SnO2 as such can be used as metal oxide layer 3 and SnO2 in combination with Pd catalyst layer 2 in another sensor.

A gas sensor matrix according to another embodiment of the invention has at least two types of gas sensors according to an embodiment of the invention, large sensor type and small sensor type. A gas sensor matrix according to another embodiment of the invention has at least two types of gas sensors according to an embodiment of the invention, but one type has a great sensitivity and another one has a lesser sensitivity for the same gas in same conditions. This can be achieved by the number of the electrodes in the active area in one embodiment, but in another embodiment by the mechanical size. A gas sensor matrix according to an embodiment of the invention comprises at least one gas sensor according to the known techniques in combination with a gas sensor of the type of large sensor type or a small sensor type, according to an embodiment of the invention. In such an embodiment, intercalibration of various sensors can be achieved. According to an embodiment of the invention the matrix can be curved, according to another embodiment of the invention even into tubular geometry to provide the flow through the tube.

According to an embodiment of the invention the substrate on which the active area with the electrodes are formed is silicon. In another exemplary embodiment the substrate can be a polymer of high temperature resistant below 300° C., or a ceramic substrate suitable for the elevated temperatures even up to 500° C. However, the temperature values are just examples and are not limiting the substrate only to mentioned. According to an embodiment of the invention even a lower temperature-resistant substrate can be used, if in such an embodiment the heating were limited according to the substrate temperature behaviour.

A gas measurement device according to an embodiment of the invention comprises at least a sensor according to an embodiment of the sensor. A gas measurement device according to another embodiment of the invention comprises at least a sensor matrix according to an embodiment of the sensor.

A gas measurement system according to an embodiment of the invention comprises at least two gas measurement devices according to an embodiment of the sensor. In such an embodiment, a further variant comprises also a means to be used accordingly to be used for collecting data and/or transfer data from at least one of said devices. In an even a further variant of such an embodiment of the invention, the system comprises means for performing calibration, measurement, and/or control of the heating of the active area. At least one of mentioned operations can be performed by a software means arranged to implement the measurement and/or the maintaining routines to control at least one sensor in a device and/or in a system.

A measurement circuit according to an embodiment of the invention, for the MOS gas sensor, is illustrated in FIG. 4. There are shown two distinguished and/or independent electrical measurements circuits that are the temperature measurement and its control circuit. According to an embodiment of the invention they can be carried out in the heater layer 6 and gas sensor measurement and its control circuit carried out in the layer formed by metal electrodes 4 and semiconductor metal oxide 3. However, the embodiment in FIG. 4 is only illustrative example and does not limit the scope of the invention only to the shown.

In a preferred embodiment of the present invention, where the electrode configuration facilitates transmission line model test pattern (FIGS. 3b and 3c) the sheet resistance (Rs) and contact resistance (Rc) components of the total resistance can be distinguished in a way illustrated in FIG. 5. In this kind of an embodiment, the measurement is carried out sequentially between electrode pairs having different L/W-value, where L/W means length/width ratio of the electrode pair. Length is the total length of the electrode including fingers of the interdigital design and width is the gap between electrode pair. When one sensor contains more than one electrode pair with different L/W value, the measured total resistance can be processed in a way presented in FIG. 5 to distinguish Rc and Rs components. The case shown in FIG. 5 can be embodied for example with the active area structure shown in FIG. 3c. The measured total resistance is processed in a way presented in the FIG. 5 to obtain the Rc and Rs values. The remaining resistance component Rg, grain boundary resistance, (FIG. 4.) can be neglected in the case of dense thin film material, like ALD-deposited metal oxide, or understood as a part of sheet resistance component of the total resistance. The sheet resistance component can be used for selectivity enhancement as some gases may give more response to Rc than Rs and vice versa. Furthermore, controlling Rc reduces drift observed in total resistance.

According to an embodiment of the invention, in an electrode configuration, the L/W values cover at least one order of magnitude of the L/W-range. In an embodiment concerning a sensor matrix, in such an embodiment there can be a first plurality of sensors with a first L/W values in a first range. According to an embodiment of the invention there can be additionally also a second plurality of sensors with a second L/W values in a second range. According to an embodiment of the invention the ranges are different. According to an embodiment of the invention the ranges overlap.

Although FIG. 5 illustrates utilisation of a linear signal-processing model for the shown data, it should be understood as an example only and also that according to another embodiment of the invention also non-linear match can be used to better take into account the departures of the non-ideal components.

According to an embodiment of the invention, the sensor contains a buried electrode 5. It can be utilized several ways in sensor measurements. According to an embodiment of the invention utilising micro hot plate structure, the heater resistor relatively close to the sensor layer, typically isolated by a dielectric material, like silicon oxide or silicon nitride. Especially, if the exact temperature will be maintained in the sensor, regardless of lifetime and outdoor conditions, the heater voltage is needed to be varied. Furthermore, high accuracy measurement requires also correct absolute temperature set-point for the sensor, which leads also to the slight differences in heater voltages between individual sensors. The heater voltage can influence on the sensor measurement uncontrollable way through capacitive coupling between sensor and heater layers. In a preferred embodiment of the invention, the contribution of the heater voltage to the sensor measurement can be improved or even eliminated, in an embodiment of the invention, by grounding the buried electrode 5.

In a preferred embodiment, the bias voltage is applied to the buried electrode. The influence of this bias voltage is illustrated theoretically in the FIG. 6 and demonstrated in the FIG. 7. Negative bias increases the total sensor resistance as predicted by the theory. In this example the sensor design has SnO2 semiconductor oxide, ca. 300 nm SiO2 insulator between buried electrode and sensor layer. Depending on the polarity of the bias, the depletion layer in the insulator-semiconductor interface is altered influencing thus on the sensor resistance. The feature can be utilized in sensor calibration and in the measurement algorithm to control the drift. It can also be utilized to enhance dynamic range of the sensor response by giving bias voltage for the buried electrode depending on the sensor resistance. Energy diagram illustrates theoretically the influence of the applied negative bias voltage on the buried electrode to the gas sensitive semiconductor layer. In this example semiconductor layer is SnO2 and insulator material SiO2.

Usually the transducer model of the MOS gas sensor assumes the electronic charge carriers contribute only—not ionic charge carriers. In one preferred embodiment of the present invention this problem is overcome by applying ac voltages for the sensor resistance measurement. According to an embodiment of the invention, a suitable frequency is 10-100000 Hz, but in a preferred embodiment 10-1000 Hz. According to an embodiment of the invention, the frequency is in the range 100-10000. According to an embodiment of the invention, the frequency is in the range 1000-1000000. By using ac voltage, the polarization effects on the material interfaces and grain boundaries due to slow contribution of the ionic carriers can be significantly reduced in an embodiment of the invention, thus reducing the drift. In a preferred embodiment, the ac voltage is applied in all electrode-pairs, namely in all sensor electrodes as well as the bias in buried electrode is modulated.

Temperature measurement circuit, according to an embodiment of the invention, measures either resistance of the heater resistor or resistance of the temperature sensor integrated into the heater layer. In another preferred embodiment heater voltage and heater current are measured facilitating heater power measurement. In both cases it is crucial to select the heater resistor material so that resistor's temperature coefficient of resistance is high. Examples of such materials are platinum and tungsten. The result is sensitive temperature measurement and control circuit that facilitates highly accurate and reliable sensor measurement. Furthermore, in another preferred embodiment, the sensitive temperature measurement facilitates measurement of calorimetric output due to combustion reactions taking place in heated sensor surface as demonstrated in FIG. 8. The integrated calorimetric and surface and contact potential measurements in one sensor component facilitate better selectivity and wider dynamic ranges regarding different gases and concentrations than could provide one sensor output alone.

It is exemplary demonstrated in FIG. 8 the role of heater material for obtaining highly sensitive temperature measurement and feasible application for measuring independent calorimetric output from the MOS sensor. The measurement has been carried out with two different sensor types with two parallel samples of each type; one sensor type consisted of Pt heater material (FIGS. 8a and 8b) and second consisted of Si-heater material (FIGS. 8c and 8d). The sensor responses (resistances) from the sensor layer (FIGS. 8c and 8d) and heater layer (FIGS. 8b and 8d) are measured when exposed simultaneously to high concentration (4000 mg/m3) of hexane vapour. In both cases the sensor response (FIGS. 8a and 8c) to hexane is high, but the heater resistance response is measurable only when the heater is consisted of platinum (FIG. 8c). Hexane is mentioned only as an example without intention to limit.

a) Sensor resistance in Sensor#1 with Pt-heater due to exposure to 4000 mg/m3 hexane vapour.

b) Heater resistance in Sensor#1 with Pt-heater due to exposure to 4000 mg/m3 hexane vapour.

c) Sensor resistance in Sensor#2 with silicon-heater due to exposure to 4000 mg/m3 hexane vapour.

d) Heater resistance in Sensor#2 with silicon-heater due to exposure to 4000 mg/m3 hexane vapour.

In this example, Pt heater exhibit sufficient temperature coefficient of resistance for successful measurement while silicon heater does not.

In general, the gas sensor device and measurement method of the present invention facilitate mass fabrication compatibility with very high quality and reproducibility. By combining all advantages provided by the present sensor device and its measurement principle, the absolute sensor resistance can be deployed as a sensor signal and the result is extremely reliable and accurate MOS gas sensor.

1-18. (canceled)

19. A micro hot-plate solid-state gas sensor comprising
a metal electrode layer (5) between a semiconductor oxide layer (3) and a heater metal layer (6), the metal electrode layer (5) is configured to control a thickness of a depletion layer of the semiconductor oxide layer (3) by applying a bias voltage to the metal electrode layer (5), and
insulator layers (1,7,8) between the semiconductor oxide layer (3), metal electrode layer (5) and heater metal layer (6).

20. The micro hot-plate solid-state gas sensor according to claim 19, wherein said semiconductor oxide layer (3) is coated with a gas species specific catalytic layer (2).

21. The micro hot-plate solid-state gas sensor according to claim 19, wherein an electrode configuration of said micro hot-plate solid-state gas sensor comprising at least three electrode pairs with each forming different electrode pattern regarding total electrode length and gap width ratio.

22. The micro hot-plate solid-state gas sensor according to claim 19, wherein said micro hot-plate solid-state gas sensor has a thin film metal oxide semiconductor gas sensor material integrated into the micro hot plate in the fabrication process.

23. The micro hot-plate solid-state gas sensor according to claim 22, wherein said thin film metal oxide semiconductor gas sensor material integrated into the micro hot plate fabrication process is made using atomic layer deposition process.

24. The micro hot-plate solid-state gas sensor according to claim 19, wherein said micro hot-plate solid-state gas sensor comprises at least one high-resistance-temperature-coefficient metal applied for heater resistor and/or arranged to be utilizable at a heater measurement.

25. A method for gas measurement comprising
applying a bias voltage to a metal electrode layer (5) of a micro hot-plate solid-state gas sensor for controlling a thickness of a depletion layer of a semiconductor oxide layer (3), the micro hot-plate solid-state gas sensor comprising the metal electrode layer (5) between the semiconductor oxide layer (3) and a heater metal layer (6), and insulator layers (1,7,8) between the semiconductor oxide layer (3), metal electrode layer (5) and heater metal layer (6).

26. The method according to claim 25, wherein the method further comprising sensor resistance measurement and signal processing carried out by using a transmission line-type measurement for distinguishing Rc and Rs components from a total resistance

27. The method according to claim 25, wherein the method further comprising sensor resistance measurement carried out by applying AC voltage in the frequency of 10-100000 Hz.

28. The method according to claim 25, wherein the method further comprising a measurement of a sensor temperature from a heater layer and applying a heater resistance measurement for a calorimetric measurement of a presence of high concentration of combustible gases.

29. The method according to claim 25, wherein the method further comprising deploying absolute resistance values as a sensor output directly correlating to a concentration of specified gas.

30. A gas measurement device comprising a micro hot-plate solid-state gas sensor according to claims 19-24.

31. A gas measurement device according to claim 30, wherein the gas measurement device is arranged to be portable.

32. A computer program comprising code means for performing the method according to claims 25-29.

33. A carrier medium carrying the computer executable program of claim 32.
